(19) United States
(12) Patent Application Publication
(10) Pub. No.: US 2016/0257560 A1
(43) Pub. Date: Sep. 8, 2016

(54) MEMS DEVICE

(71) Applicant: KABUSHIKI KAISHA TOSHIBA, Tokyo (JP)

(72) Inventor: Masaki YAMADA, Saitama Saitama (JP)

(21) Appl. No.: 14/845,025

(22) Filed: Sep. 3, 2015

(30) Foreign Application Priority Data
Mar. 6, 2015 (JP) 2015-044746

(51) Int. Cl. B81B 7/00

(52) U.S. Cl. CPC B81B 7/0077

(57) ABSTRACT

According to one embodiment, a MEMS device includes a MEMS element including a movable portion and provided on a substrate, a first protective film provided above the substrate and the MEMS element while shaping a cavity to accommodate the MEMS element, a sealing layer configured to cover the first protective film and a second protective film provided on the sealing layer. An outer end of the protective film is located on an outer side of an end of the cavity on the substrate, and the ratio between distance A defined from the outer end of the sealing layer to the end of the cavity and thickness B of the first protective film, B/A, is set in a range of 0.25 to 0.52.

### CROSS-REFERENCE TO RELATED APPLICATIONS

This application is based upon and claims the benefit of priority from Japanese Patent Application No. 2015-044746, filed Mar. 6, 2015, the entire contents of which are incorporated herein by reference.

### FIELD

Embodiments described herein relate generally to a micro-electro-mechanical-systems (MEMS) device which uses a MEMS element.

### BACKGROUND

A MEMS device, which an electronic component containing a MEMS element, needs to comprise a cavity as an operating space for the movable portion of the MEMS element. Such a cavity is formed to have a structure in which, for example, a dome-like thin film (cap layer having a hollow structure) comprising a plurality of through-holes, a sealing layer configured to close the through-holes, and a surface protection film configured to prevent the invasion of moisture and mobile ions, etc., are stacked one on another.

Conventionally, MEMS devices comprising a multilayered structure for forming a cavity entail a drawback that the characteristics of the MEMS element are deteriorated due to cracks or the like, made in the cap layer or the surface protection film, thus degrading the reliability of the device.

### BRIEF DESCRIPTION OF THE DRAWINGS

FIG. 1 is a sectional view showing a brief structure of a MEMS device according to the first embodiment.

FIGS. 2A to 2F are sectional views showing a manufacturing process of the MEMS device shown in FIG. 1.

FIG. 3 is a schematic diagram of a thin-film dome used to specify the dimensions of each part thereof.

FIG. 4 is a characteristic diagram indicating the relationship between the projection of a sealing layer and the maximum stress.

FIG. 5 is a characteristic diagram indicating the relationship between the projection of the sealing layer and the occurrence of cracks.

FIG. 6 is a characteristic diagram indicating the relationship between a ratio of a thickness of the protective film to a distance of the sealing layer B/A and the maximum stress, and also the occurrence of cracks, to describe the first embodiment.

FIG. 7 is a characteristic diagram indicating the relationship between a ratio of a thickness of the protective film to a distance of the sealing layer C/A and the maximum stress, and also the occurrence of cracks, to describe the second embodiment.

### DETAILED DESCRIPTION

In general, according to one embodiment, a MEMS device comprises a MEMS element comprising a movable portion and provided on a substrate, a first protective film provided above the substrate and the MEMS element while shaping a cavity to accommodate the MEMS element, and comprising through-holes communicated with the cavity, a sealing layer provided on the first protective film to cover the first protective film and a second protective film provided on the sealing layer to cover the sealing layer. The sealing layer, provided on the first protective film, comprises an outer end located on an outer side of an end of the cavity on the substrate, and the ratio, B/A, of thickness B of the first protective film to the distance A, defined from the outer end of the sealing layer to the end of the cavity in the range of 0.25 to 0.52.

MEMS devices of embodiments will now be described with reference to drawings.

### First Embodiment

### Structure

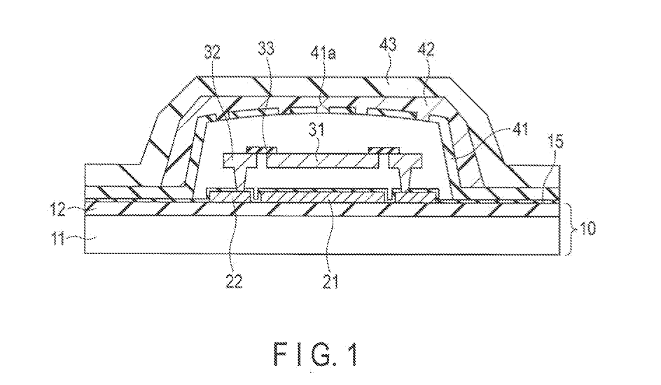

FIG. 1 is a sectional view showing a brief structure of a MEMS device according to the first embodiment.

In this figure, numeral 10 denotes a support board in which an insulating layer 12 of a silicon oxide film or the like, was formed on a Si substrate 11. The substrate 10 may be provided with elements such as field-effect transistors which form a logic circuit, a memory circuit, etc.

On the support board 10, a MEMS element comprising a lower electrode 21, an anchor portion 22,32, an upper electrode 31, a spring member 33 and the like, is formed. It should be noted that the structure of the MEMS element is not limited to those which will be discussed in the embodiments, and further the embodiments are applicable to such a device that comprises not only a MEMS element in its cavity, but also a movable portion.

On the support board 10, a lower electrode (first electrode) 21 as a fixed electrode, an anchor portion 22 configured to fix a beam portion are formed. The lower electrode 21 is formed of, for example, aluminum (Al) or an alloy containing aluminum as a main component, into, for example, a rectangle. The material of the lower electrode 21 is not necessarily limited to these, but copper (Cu), platinum (Pt), tungsten (W) or the like may be used. Furthermore, the lower electrode 21 may be divided into plurality.

A capacitor insulating film 15 of, for example, a silicon nitride film having a thickness of 100 nm is formed on the surface of the lower electrode 21 so as to cover. As the material of the capacitor insulating film 15, not only a silicon nitride film, but also a high-k film having a dielectric constant higher than that of SiOx or SiN may be used.

An upper electrode (second electrode) 31 as a movable electrode is provided above the lower electrode 21 to face thereto. The upper electrode 31 is formed of, for example, a ductile material such as aluminum, an aluminum alloy, Cu, Au or Pt. This electrode may be formed of, not only a ductile material, but also a brittle material such as tungsten (W). Further, an anchor portion 32 of the same material as the upper electrode 31 is formed on the anchor portion 22.

A part of the upper electrode 31 is connected to the anchor portion 32 fixed to the anchor portion 22 by a spring member (beam portion) 33. In other words, one end of the spring member 33 is fixed to the anchor portion 32, and the other end is being fixed to the upper surface of the upper electrode 31. Further, the spring member 33 and the anchor portions 22 and 32 are provided at locations in the upper electrode 31. Each spring member 33 is formed of, for example, a silicon nitride film and into a meander shape. Thus, each spring member 33 has elasticity. With these spring members 33, the upper electrode 31 is movable vertically.

A cap layer (first protective film) 41 of a silicon oxide film is formed to cover the upper electrode 31, the anchor portion 32 and the spring member 33 while making a hollow region around these members. The cap layer 41 includes, for example, circular through-holes 41a formed therein, used to remove a sacrificial layer.

A resin sealing layer 42 is formed on the cap layer 41 so as to close the through-holes 41a of the cap layer 41. The resin sealing layer 42 is formed not only in the upper surface of the cap layer 41 but in the side surface of the cap layer 41. Further, an insulating layer (second protective film) 43 of SiN or the like, which functions as a moisture-proof film, is formed so as to cover the cap layer 41 and the resin sealing layer 42.

As described above, the cavity (thin-film dome) as an operation space for the movable portion of the MEMS element is formed from the three-layer structure of the cap layer 41, the resin sealing layer 42 and the insulating layer 43.

### Manufacturing Method

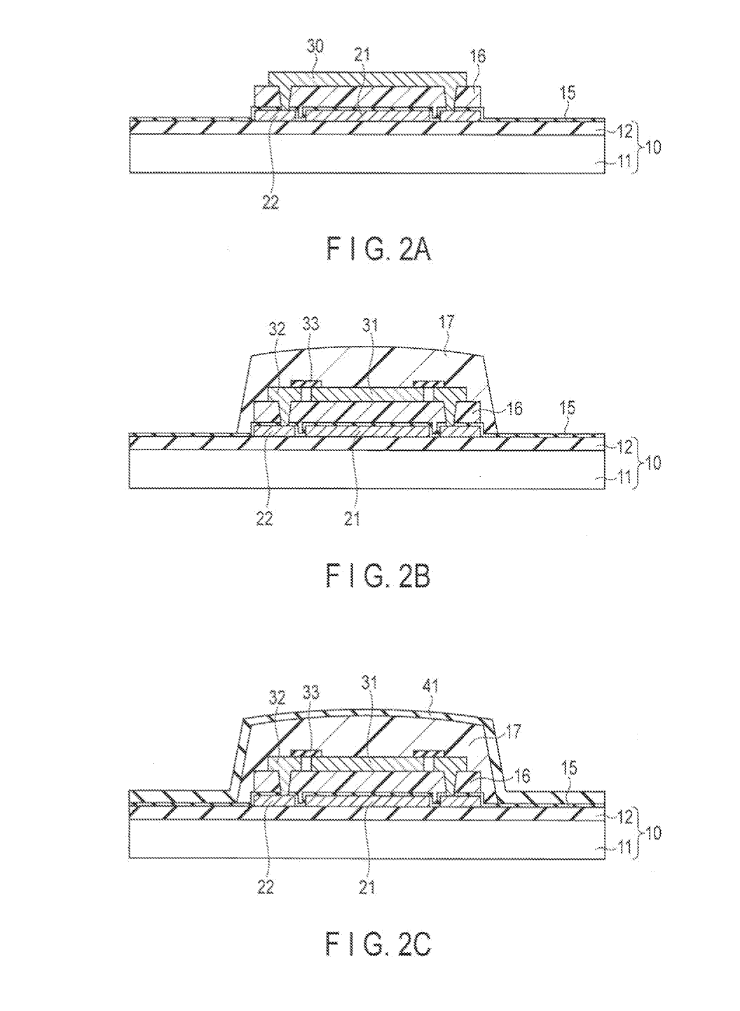

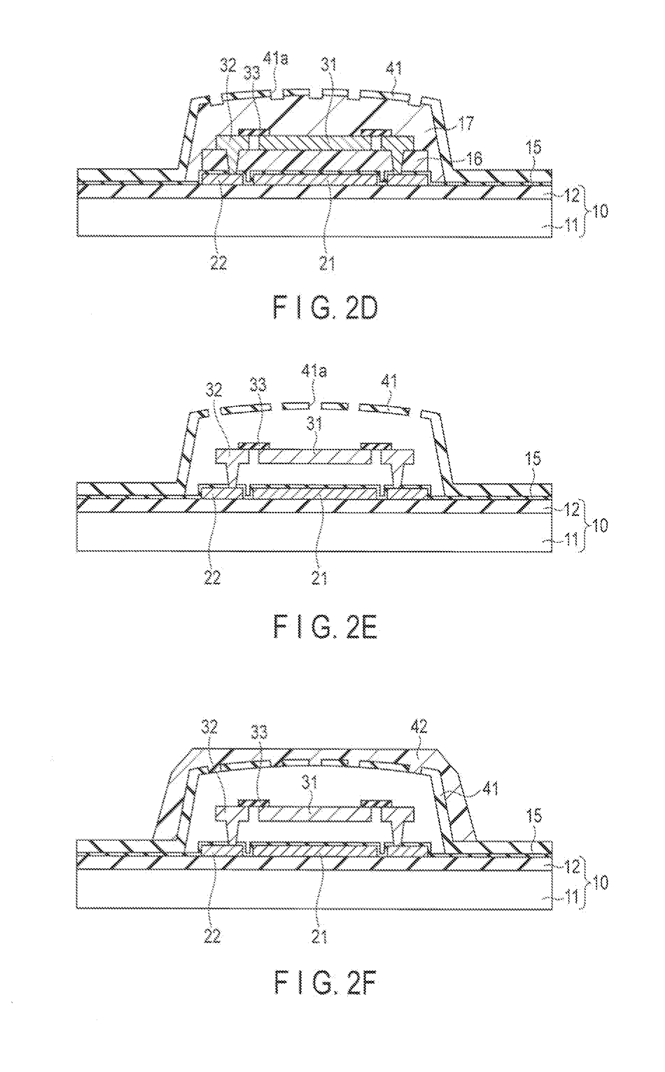

Next, the manufacturing method of the MEMS device of this embodiment will now be described with reference to FIGS. 2A to 2F.

First, as shown in FIG. 2A, a metallic film of aluminum or the like is formed to have a thickness of several hundreds of nanometers to several micrometers on the support board 10 in which the insulating layer 12 of silicon oxide or the like, is formed on the semiconductor substrates 11 of Si or the like. Then, by patterning the metallic film, the lower electrode 21 and the anchor portion 22 are formed.

Subsequently, the capacitor insulating film 15 of SiN or the like is formed by chemical vapor deposition (CVD) or the like on the support board 10 so as to cover the lower electrode 21 and the anchor portion 22. As a material of the capacitor insulating film 15, not only a silicon nitride film, but a high-k film, which a dielectric constant higher than that of SiOx or SiN, may be used.

Next, an organic material such as polyimide is applied as the first sacrificial layer 16, and thereafter the first sacrificial layer 16 is patterned into a desired form. More specifically, the pattern is performed so that the first sacrificial layer 16 remains on the lower electrode 21 and the anchor portion 22. Further, an opening is made at the location above the anchor portion 22 and in the opening, the insulating layer 15 is removed.

Note that the patterning may be carried out in the following manners. That is, a resist pattern is formed by ordinary lithography on the first sacrificial layer 16, and then the patterning is performed by reactive ion etching (RIE) using the resist pattern as a mask. Or, an SiO film or the like formed on the first sacrificial layer 16 is patterned to form a hard mask using a resist pattern formed by ordinary lithography, followed by the RIE method or wet etching, and the first sacrificial layer 16 is patterned using the hard mask.

Next, the metallic film 30 of aluminum or the like is formed to have a thickness of several hundred nanometers to several micrometers, and the unnecessary part is removed, for forming an upper electrode and an anchor portion.

Subsequently, as shown in FIG. 2B, the metallic film 30 is patterned to form the upper electrode 31 and the anchor portion 32. Then, the spring member (beam portion) 33 which connects the upper electrode 31 and the anchor portion 32 together is formed. For the formation of the spring member 33, a silicon nitride film or the like, to be used as the material of the spring member 33, may be formed, and then patterned by RIE into the shape of the spring member 33. Here, the gap between the upper electrode 31 and the anchor portion 32 may be filled up with the same material as that of the first sacrificial layer 16 in advance.

FIG. 2B shows that the anchor portion 32 is formed above the anchor portion 22 and the spring member 33 is fixed to the anchor portion 32. But, note that the spring member 33 may be fixed directly to the anchor portion 22. When the anchor portion 32 is formed on the anchor portion 22 to make the portion to which the spring member 33 is fixed to have the same height as the upper electrode 31 as shown in FIG. 2B, the spring member 33 can be formed flat in a plane parallel to the surface of the upper electrode 31.

Note that the order of processes which form the upper electrode 31 and the spring member 33 may be arbitrary. That is, the spring member 33 may be patterned after formation of the upper electrode 31, or the upper electrode 31 may be formed after patterning the spring member 33.

Next, the process proceeds to the formation of the thin-film dome.

As shown in FIG. 2C, the second sacrificial layer 17 is formed by applying an organic material such as polyimide over the upper electrode 31, the anchor portion 32, and the spring member 33 to cover these. The second sacrificial layer 17 is formed by applying the material to have a thickness of several hundred nanometers to several micrometers, and patterning the material into a desired form. As to the patterning method, a resist pattern may be formed by ordinary lithography on the second sacrificial layer 17, and then patterned by RIE. Or, an SiO film or the like formed on the second sacrificial layer 17 may be patterned to form a hard mask, and the second sacrificial layer 17 may be patterned using the hard mask.

Next, in order to form the thin-film dome, an insulating film of SiO or the like is formed by CVD or the like to have a thickness of several hundred nanometers to several micrometers. Then, a resist (not shown) is formed by ordinary lithography, followed by patterning, and thus the cap layer (first protective film) 41 is formed.

Subsequently, the cap layer 41 is subjected to RIE or wet etching to form, for example, circular through-holes 41a therein, for removal of the first and second sacrificial layers 16 and 17 as shown in FIG. 2D.

Subsequently, with an asking technique using gaseous O₂, the first and the second sacrificial layers 16 and 17 are removed through the through-holes 41a as shown in FIG. 2E. In this manner, a hollow structure (cavity) is formed around the upper electrode 31 and the spring member 33. In other words, the upper electrode 31 and the spring member 33 are movable now.

Next, as shown in FIG. 2F, the resin sealing layer 42 is formed by applying an organic material such as polyimide, followed by patterning. As to the patterning method, the resin sealing layer 42 may be exposed and developed after being applied to have a thickness of several hundred nanometers to several micrometers. Or, after forming a resist pattern by ordinary lithography on the resin sealing layer 42, the resin sealing layer 42 may be processed by RIE. Further, an SiO film or the like formed on the resin sealing layer 42 may be patterned to form a hard mask, and the resin sealing layer 42 may be patterned using the hard mask.

In patterning of the resin sealing layer 42, it suffices if the sealing layer 42 remains on the upper surface and the side surface of the cap layer 41.

The illustration of the process from this on is not provided, but the insulating layers (second protective film) 43 of SiN or the like, which functions as a moisture-proof film is formed to have a thickness of several hundred nanometers to several micrometers, on the entire surface of the substrate including the resin sealing layer 42 by CVD or the like, and thus the structure shown in FIG. 1 is completed.

The process of forming the MEMS element and the thin-film dome itself is completed here, but after that, if necessary, further processes of connecting the MEMS element with a semiconductor device and/or electrically connecting the element with the exterior are performed.

### Size Designing

Next, regulation in size on the structural part of the thin-film dome, which is a feature of the embodiment, will now be described.

In order to suppress the degradation in characteristics and reliability of the MEMS element, it is necessary to prevent the occurrence of cracks in the multilayer film which forms the thin-film dome. In order to achieve this, the authors of the embodiments conducted intensive studies and found out that the occurrence of cracks in the multilayered film could be suppressed by the following settings in the patterning of the resin sealing layer 42.

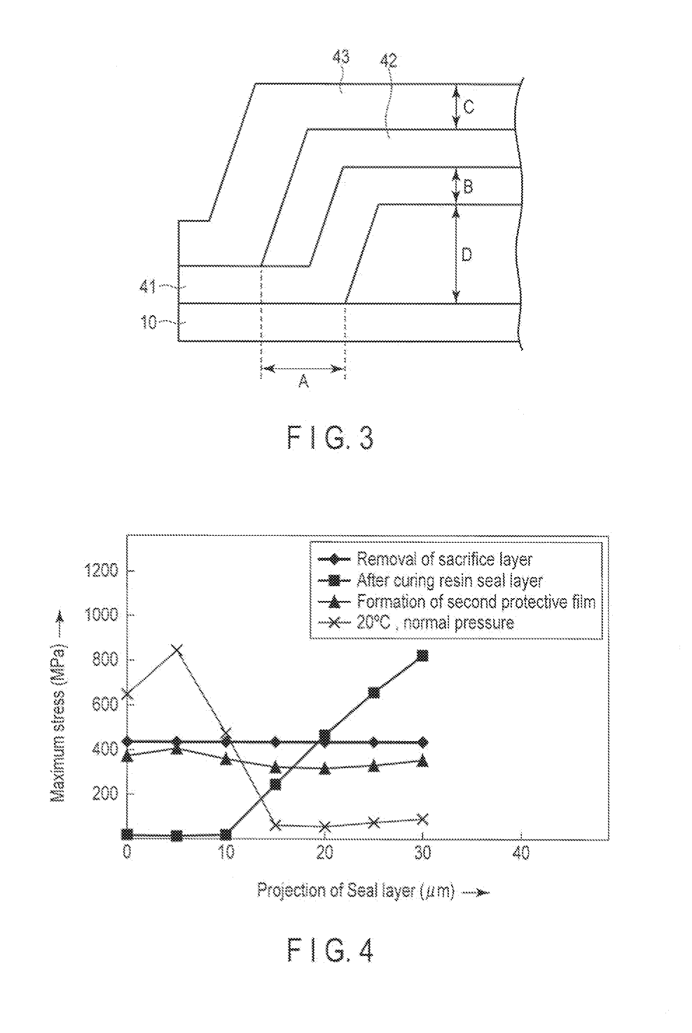

That is, as shown in FIG. 3, the distance from the outer end of the sealing layer 42 (outer end of the lowermost part of the sealing layer 42) on the first protective film 41 to the end (inner end of the lowermost part of the first protective film 41) of the cavity on the substrate 10, that is, the projection of the sealing layer 42, is set to A. Further, the thickness of the first protective film 41 is set to B, the thickness of the second protective film 43 is set to C, and the height of the cavity is set to D.

The results of simulations carried out on the maximum stress when A was changed under the conditions that B =5 μm, C =5 μm and D =15 μm is shown in FIG. 4.

During the process of removal of the first and second sacrificial layers 16 and 17 (sacrificial layer removal process) and the process of forming the second protective film 43 (second protective film formation process), the stress does not substantially change if the projection A of the sealing layer 42 is changed. Further, the varied stress, if any, falls within the tolerance from a viewpoint of the occurrence of cracks in the multilayer film. After the process of curing the sealing layer 42 (after curing the resin sealing layer), the stress starts to increase when the projection A of the sealing layer 42 exceeds 10 μm. When the projection A of the sealing layer 42 is equal to 30 μm, the stress increases up to 800 MPa, which is considered to cause the cracks in the multilayer film.

In the state where the resin film is finally formed (20° C., normal pressure), the stress is relatively great (650 MPa) when the projection A of the sealing layer 42 =0 μm, and the stress increases to the peak (850 MPa) when the projection A is 5 μm. After that, if the projection A of the sealing layer 42 exceeds 5 μm, the stress gradually reduces and it becomes sufficiently small at A =15 μm. From this on, the stress becomes substantially constant.

In order to prevent the occurrence of cracks in the multilayer film, it is necessary to control the maximum stress to be a predetermined value or less in each process.

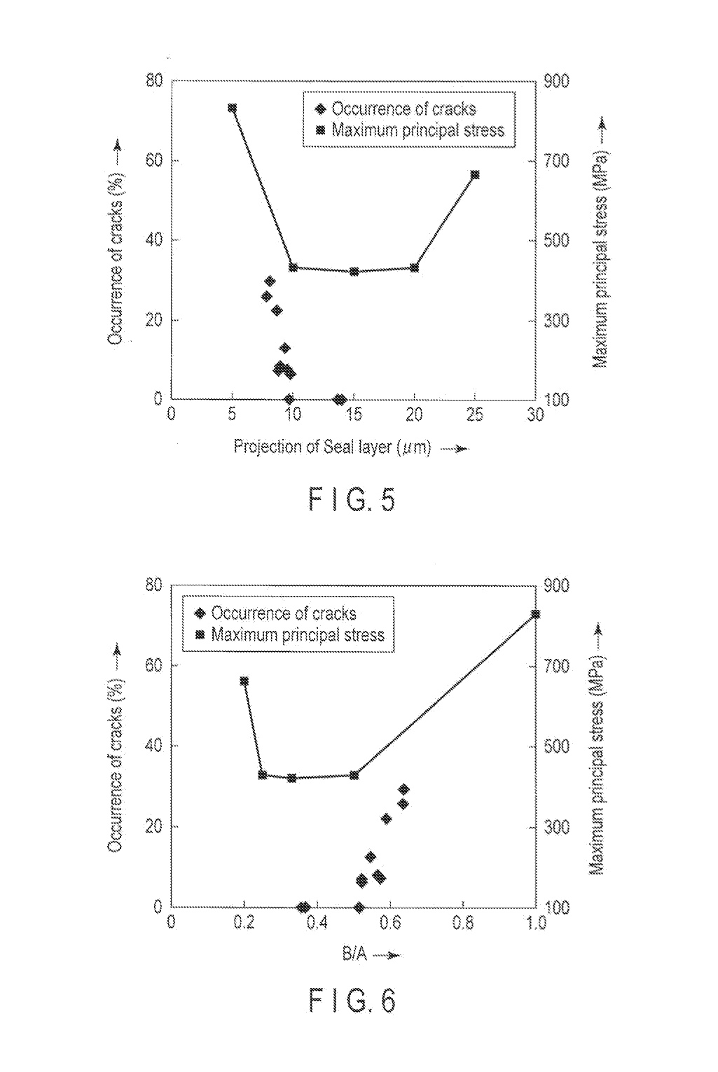

Here, the results of calculation on the maximum principal stress and the rate of occurrence of cracks in connection with the projection A of the sealing layer 42 are summarized in FIG. 5. Maximum principal stress is the largest value of the stress in each process. Here, thicknesses B and C of the first and second protective films 41 and 43 are both fixed at constant (B =C =5 μm).

As can be seen from FIG. 5, when the projection A of the sealing layer 42 is less than 10 μm, the maximum principal stress increases, and when the projection A exceeds 20 μm, the maximum principal stress increases rapidly. Here, a great number of cracks occur in the region where the projection A of the sealing layer 42 is 10 μm or less. Therefore, it is understood that the projection A should desirably be in the range of 10 to 20 μm.

Note that in FIG. 5, thicknesses B and C of the protective films 41 and 43 are both set to be constant (5 μm), but if the thicknesses changes, the characteristics shown in FIG. 5 may also change.

For this reason, in this embodiment, the maximum principal stress and the rate of occurrence of cracks were calculated in terms of B/A. The results were as shown below.

FIG. 6 shows changes in the maximum principal stress and the rate of occurrence of cracks with respect to B/A. Here, the measurements were carried out while thickness C of the second protective film 43 was fixed substantially at constant (C =5 μm) and the height D of the cavity was fixed substantially at constant (D =15 μm), whereas the projection A and thickness B of the first protective film 41 were varied in many ways.

It can be understood from FIG. 6 that when B/A is in the range of 0.25 to 0.52, the stress is extremely small and the rate of occurrence of cracks is sufficiently low. Note that the lower limit of B/A is obtained from the maximum principal stress. This is because the maximum principal stress increases rapidly when B/A is less than 0.25. Further, note that the upper limit of B/A is obtained by detecting the occurrence of cracks. This is because cracks occur when B/A exceeds 0.52.

In addition, the desirable range of B/A provided above was constant unless dimensions of C and D changed greatly. Specifically in the range usually used as dimensions of C and D (C=4 to 6 μm, D=10 to 20 μm), the characteristics shown in FIG. 6 did not substantially change. Therefore, it can be understood that in the case where the dimensions of C and D are within a usual range, the occurrence of cracks can be controlled by setting B/A within the range of 0.25 to 0.52.

### Advantage of Embodiment

Thus, according to this embodiment, the stress loaded on the multilayer film, which forms the thin-film dome can be controlled to a sufficiently small level by setting the relationship between the projection A of the resin sealing layer 42 and thickness B of the first protective film 41 (B/A) to 0.25 to 0.52. Thus, the occurrence of cracks in the multilayer film, which forms the cavity to accommodate the movable member of the MEMS element, can be controlled, thus making it possible to improve the reliability of the element.

### Second Embodiment

In the first embodiment described above, the relationship between the projection A of the resin layer 42 and thickness B of the first protective film 41 is specified, but instead, the relationship between the projection A of the resin layer 42 and thickness C of the second protective film 43 may be specified.

The structure of the MEMS device and the manufacturing method thereof are the same as those of the first embodiment provided above. In this embodiment, the maximum principal stress and the rate of occurrence of cracks were calculated in terms of C/A. The results are shown below.

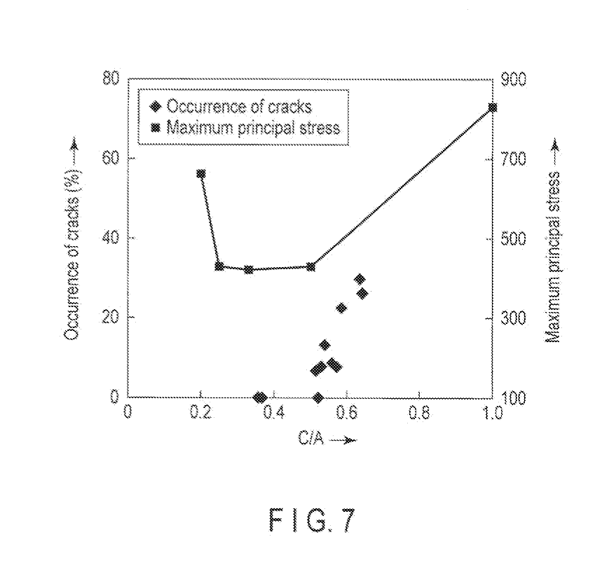

FIG. 7 shows changes in the maximum principal stress and the rate of occurrence of cracks with respect to C/A. Here, the measurements were carried out while the thickness B of the first protective film 41 was fixed substantially at constant (B=5 μm) and the height D of the cavity was fixed substantially at constant (D=15 μm), whereas the projection A and the thickness C of the second protective film 43 were varied in many ways.

It can be understood from FIG. 7 that when C/A is in the range of 0.25 to 0.52, the stress is extremely small and the rate of occurrence of cracks is sufficiently low. Note that the lower limit of C/A is obtained from the maximum principal stress. This is because the maximum principal stress increases rapidly when C/A is less than 0.25. Further, note that the upper limit of C/A is obtained by detecting the occurrence of cracks. This is because cracks occur when C/A exceeds 0.52.

In addition, the desirable range of C/A provided above was constant unless dimensions of B and D greatly changed. Specifically in the range usually used as dimensions of B and D (B=4 to 6 μm, D=10 to 20 μm), the characteristics shown in FIG. 7 did not substantially change. Therefore, it can be understood that in the case where the dimensions of B and D are within a usual range, the occurrence of cracks can be controlled by setting C/A within a range of 0.25 to 0.52.

It can be also understood that when the dimensions of D are in the usual range, the occurrence of cracks can be controlled even more reliably by setting the relationship between the projection A of the resin layer 42 and each of the thicknesses B and C of the first and second protective films 41 and 43 within a range of 0.25 to 0.52 (That is, B/A=0.25 to 0.52 and C/A=0.25 to 0.52).

Thus, according to this embodiment, the stress loaded on the multilayer film, which forms the thin-film dome can be controlled to a sufficiently small level by setting the relationship between the projection A of the resin sealing layer 42 and thickness C of the second protective film 43 (C/A) to 0.25 to 0.52. Thus, the occurrence of cracks in the multilayer film can be controlled, thus making it possible to improve the reliability of the element.

### Third Embodiment

In the first or second embodiment described above, the relationship between the projection A of the resin layer 42 and thickness B of the first protective film 41, or thickness C of the second protective film 43 is specified, but instead, the relationship between the projection A of the resin layer 42 and the height D of the cavity may be specified.

In the first or second embodiment, even if B/A and C/A are set in respective desirable ranges, a crack may still occur if the height D of the cavity varies extremely. In this embodiment, changes in the maximum stress and the rate of occurrence of cracks with respect to D/A were measured as in the cases of B/A and C/A. The results indicated that in the case where the dimensions of B and C are within a usual range, the stress can be sufficiently reduced and therefore the occurrence of cracks can be controlled by setting D/A within the range of 0.9 to 3.6.

Moreover, in order to prevent the occurrence of cracks reliably in consideration of the dimensions of B and C as well, all of B/A, C/A and D/A should be just set in the respective desirable ranges. More specifically, when the projection A of the resin sealing layer 42, thicknesses B and C of the first and second protective films, and the height D of the cavity are set to satisfy the following relationships, respectively:

B/A =0.25 to 0.52

C/A =0.25 to 0.52

D/A =0.9 to 3.6

the stress loaded on the multilayer film, which forms the thin-film dome can be controlled to a sufficiently small level, and thus the occurrence of cracks in the multilayer film can be reliably controlled.

### Modification

The embodiments are not limited to those described above.

Those embodiments are described on the assumption that the MEMS element in the thin film dome is a variable capacitance element, but some other type of MEMS element which requires a thin-film dome may be used. In other words, the MEMS element is not limited to a variable capacity element, but also a sensor, a filter, a switch or the like. In short, it may be any element including a movable member.

Moreover, the materials of the multilayer film which forms the thin-film dome are not limited to those mentioned in the embodiments at all. The first protective film may be any type of film as long as it can be formed at relatively low temperature (up to 250 ° C.), and a silicon-containing oxide film is desirable. Further, it is also possible to use a silicon nitride film and an amorphous silicon film. The sealing layer may be any type of film as long as it can reliably close the through-holes of the first protective film, and a polyimide-based resin is desirable. The second protective film may be any type of film as long as it has low gas permeability and excellent humidity-proof, and a silicon-containing nitride film is desirable. Further, it is also possible to use a silicon carbide film (SiC), an aluminum oxide film (Al2O3) and an aluminum nitride film (AlN).

Moreover, the materials of the multilayer film are not limited to those mentioned above, but may be changed as needed according to the specification of the device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A MEMS device comprising:
a MEMS element comprising a movable portion and provided on a substrate;
a first protective film provided above the substrate and the MEMS element while shaping a cavity to accommodate the MEMS element, the first protective film comprising through-holes communicated with the cavity;
a sealing layer provided on the first protective film to cover the first protective film; and
a second protective film provided on the sealing layer to cover the sealing layer,
wherein
the sealing layer, provided on the first protective film, comprises an outer end located on an outer side of an end of the cavity on the substrate, and
a ratio, B/A, of a thickness B of the first protective film to a distance A defined from the outer end of the sealing layer to the end of the cavity is in a range of 0.25 to 0.52.

2. The MEMS device of claim 1, wherein
a ratio, C/A, of a thickness C of the second protective film to the distance A is in a range of 0.25 to 0.52.

3. The MEMS device of claim 1, wherein
a ratio, D/A, of a height D of the cavity to the distance A is in a range of 0.9 to 3.6.

4. The MEMS device of claim 2, wherein
a ratio, D/A, of a height D of the cavity to the distance A is in a range of 0.9 to 3.6.

5. The MEMS device of claim 1, wherein
the first protective film is an silicon-containing oxide film, the sealing layer is a polyimide-based resin film, and the second protective film is a silicon-containing nitride film.

6. The MEMS device of claim 1, wherein
the sealing layer is configured to close the through-holes.

7. The MEMS device of claim 1, wherein
the sealing layer is configured to cover the cavity of the first protective film.

8. The MEMS device of claim 1, wherein
the second protective film is provided on the sealing layer and on the first protective film.

9. A MEMS device comprising:
a MEMS element comprising a movable portion and provided on a substrate;
a first protective film provided above the substrate and the MEMS element while shaping a cavity to accommodate the MEMS element, the first protective film comprising through-holes communicated with the cavity;
a sealing layer provided on the first protective film to cover the first protective film; and
a second protective film provided on the sealing layer to cover the sealing layer,
wherein
the sealing layer, provided on the first protective film, comprises an outer end located on an outer side of an end of the cavity on the substrate, and
a ratio, C/A, of a thickness C of the second protective film to a distance A defined from the outer end of the sealing layer to the end of the cavity is in a range of 0.25 to 0.52.

10. The MEMS device of claim 9, wherein
a ratio between the distance A and a height D of the cavity, D/A, is in a range of 0.9 to 3.6.

11. The MEMS device of claim 9, wherein
the first protective film is an silicon-containing oxide film, the sealing layer is a polyimide-based resin film, and the second protective film is a silicon-containing nitride film.

12. The MEMS device of claim 9, wherein
the sealing layer is configured to close the through-holes.

13. The MEMS device of claim 9, wherein
the sealing layer is configured to cover the cavity of the first protective film.

14. The MEMS device of claim 9, wherein
the second protective film is provided on the sealing layer and on the first protective film.

15. A MEMS device comprising:
a MEMS element comprising a movable portion and provided on a substrate;
a first protective film provided above the substrate and the MEMS element, to shape a cavity to accommodate the substrate and the MEMS element, the first protective film comprising through-holes communicated with the cavity;
a sealing layer configured to close the through-holes, the sealing layer being provided on the first protective layer to cover the cavity of the first protective layer; and
a second protective film provided on the sealing layer and the first protective layer,
wherein
the sealing layer, provided on the first protective film, comprises an outer end located on an outer side of an end of the cavity on the substrate, and
a ratio, B/A, of a thickness B of the first protective film to a distance A defined from the outer end of the sealing layer to the end of the cavity is in a range of 0.25 to 0.52.

16. The MEMS device of claim 15, wherein
a ratio, C/A, of a thickness C of the second protective film to the distance A is in a range of 0.25 to 0.52.

17. The MEMS device of claim 15, wherein
a ratio, D/A, of a height D of the cavity to the distance A is in a range of 0.9 to 3.6.

18. The MEMS device of claim 17, wherein
a ratio, D/A, of a height D of the cavity to the distance A is in a range of 0.9 to 3.6.
